(19) United States
(12) Patent Application Publication
(10) Pub. No.: US 2008/0164469 A1
(43) Pub. Date: Jul. 10, 2008

(54) Semiconductor device with measurement pattern in scribe region

(76) Inventors: Myoung-soo Kim, Suwon-si (KR); Yong-chan Kim, Suwon-si (KR)

Correspondence Address: LAW OFFICE OF MONICA H CHOI, P O BOX 3424, DUBLIN, OH, 430160204, US

(21) Appl. No.: 12/005,180

(22) Filed: Dec. 26, 2007

(30) Foreign Application Priority Data
Jan. 8, 2007 (KR) 2007-0002106

(51) Int. Cl. H01L 23/58

(52) U.S. Cl. 257/48; 257/E23.002

(57) ABSTRACT

A semiconductor device includes pads disposed in a chip region of a semiconductor substrate and line patterns disposed in a scribe region of the semiconductor substrate and extending toward the pads. The line patterns each have a line-width that is less than a predetermined distance between adjacent pads. Thus, respective interconnection lines connected to the pads are not short-circuited to each-other through the line patterns in the remaining scribe region after the chip region is sawed into a semiconductor chip.

### BACKGROUND OF THE INVENTION

This application claims priority under 35 USC §119 to Korean Patent Application No. 2007-0002106, filed on Jan. 8, 2007 in the Korean Intellectual Property Office, the disclosure of which is incorporated herein in its entirety by reference.

1. Field of the Invention

The present invention relates generally to semiconductor devices, and more particularly, to a semiconductor device with line patterns formed for a measurement pattern in a scribe region for preventing short-circuits.

2. Background of the Invention

Many chip regions are defined on a semiconductor wafer with a respective integrated circuit being fabricated in each of the chip regions. Each chip region defines an integrated circuit die (i.e., a semiconductor chip). The number of semiconductor chips obtained from a single semiconductor wafer may be increased by reducing the width of the scribe regions disposed between the chip regions.

Test patterns used for monitoring a fabrication process or performing an electrical test on the semiconductor chips are formed in such scribe regions. The test patterns formed in the scribe regions are removed during the separation of the semiconductor chips by sawing through the scribe regions that should not affect operation of the semiconductor chips.

FIG. 1 shows a semiconductor wafer 10 on which a semiconductor device is formed including a plurality of chip regions 12 and scribe regions 14. FIG. 2 shows an enlarged view of an example scribe region 14 between two chip regions 12. Referring to FIGS. 1 and 2, a respective set of pads 16 is disposed in each of the chip regions 12. In addition, measurement patterns 18 used for monitoring a fabrication process or conducting an electrical test are disposed in the scribe region 14.

Referring to FIG. 2, the chip regions 12 are separated from one another by the scribe region 14. Specifically, the semiconductor wafer 10 is divided into integrated circuit dies (i.e., semiconductor chips) by sawing along the scribe regions 14. For example, a removed portion 14a of the scribe region 14 corresponding to a width of a sawing blade is removed, while the remaining portion 14b of the scribe region 14 remains to surround the semiconductor chips.

In order to increase the number of semiconductor chips fabricated from the wafer 10, the width of the scribe region 14 is desired to be reduced by sawing with a thinner blade. However, because of a limit to shrinking the measurement pattern 18, the measurement pattern 18 may depart from the removed scribe region 14a and overlap onto the remaining scribe region 14b. The measurement pattern 18 disposed in the remaining scribe region 14b remains on an edge of the semiconductor chip.

FIG. 3 shows a semiconductor chip 20 that has been sawed and mounted on a substrate 30. Referring to FIG. 3, the semiconductor chip 20 is combined with the substrate 30 using a bonding wire or a bumper. The semiconductor chip 20 includes the chip region 12 and the remaining scribe region 14b disposed around the chip region 12.

A plurality of pads 16 are disposed in the chip region 12, and are connected to interconnection lines 22, respectively. Unfortunately in the prior art, the interconnection lines 22 may contact the residue 18a of a measurement pattern 18 remaining in the remaining scribe region 14b disposed around the semiconductor chip 20. Since the width of the residue 18a of the measurement pattern 18 is greater than an interval between the pads 16, the multiple interconnection lines 22 may be short-circuited to each-other via the residue 18a. Such a short-circuit may result in malfunction of the semiconductor chip 20.

### SUMMARY OF THE INVENTION

Accordingly, a measurement pattern is formed with line patterns to prevent such a short-circuit between interconnection lines in aspects of the present invention.

A semiconductor device according to an aspect of the present invention includes pads disposed in a chip region of a semiconductor substrate and line patterns disposed in a scribe region of the semiconductor substrate and extending toward the pads. The line patterns each have a line-width that is less than a predetermined distance between adjacent pads.

For example, the line-width of each line pattern is less than an interval between adjacent pads. Alternatively, the line-width of each line pattern is less than a pitch between adjacent pads.

In another embodiment of the present invention, the semiconductor device further includes a measurement pattern including a central body and the line patterns extending from the central body toward the pads.

For example, the semiconductor device includes a first set of pads disposed in a first chip region of the semiconductor substrate that is a semiconductor wafer, and includes a second set of pads disposed in a second chip region of the semiconductor substrate. In addition, the semiconductor device includes a first set of line patterns extending from a first side of the central body toward the first set of pads, and includes a second set of line patterns extending from a second side of the central body toward the second set of pads.

In an example embodiment of the present invention, the central body is a continuous rectangular body.

In another embodiment of the present invention, the measurement pattern is used for monitoring a thickness of the measurement pattern. Alternatively, the measurement pattern is used as an overlay or alignment key.

In a further embodiment of the present invention, the central body is completely contained within a removed region of the scribe region. Thus, the central body is not disposed in a remaining region of the scribe region.

In another embodiment of the present invention, the semiconductor device includes a test pattern formed in the removed region of the scribe region, and the test pattern is connected to the measurement pattern. In that case, the measurement pattern is used as a probe pad for the test pattern.

In a further embodiment of the present invention, first portions of the line patterns are disposed in a removed region of the scribe region, and second portions of the line patterns are disposed in a remaining region of the scribe region.

In another embodiment of the present invention, the measurement pattern is comprised of a conductive material.

In an alternative embodiment of the present invention, the line patterns extend through a removed region and a remaining region of the scribe region.

In a further aspect of the present invention, the line patterns are disposed in a remaining region of the scribe region after the chip region has been sawed to form an integrated circuit die. In an embodiment of the present invention, the semiconductor device includes a respective interconnection line connected to each of the pads and being disposed over a respective portion of the line patterns. In addition, the respective interconnection lines and the line patterns are each comprised of a conductive material. In that case, the respective interconnection lines connected to the pads are not short-circuited to each-other through the line patterns.

### BRIEF DESCRIPTION OF THE DRAWINGS

The above and other features and advantages of the present invention will become more apparent when described in detailed exemplary embodiments thereof with reference to the attached drawings in which:

FIGS. 1, 2, and 3 illustrate formation of measurement patterns formed in a scribe region between chip regions, according to the prior art;

FIGS. 4, 5, and 6 illustrate formation of measurement patterns formed in a scribe region between chip regions, according to example embodiments of the present invention;

FIGS. 7 and 8 each illustrate a semiconductor chip formed after being sawed away from a semiconductor wafer with a remaining scribe region according to example embodiments of the present invention; and

FIG. 9 illustrates portions of an example of the measurement patterns of FIG. 4, according to an embodiment of the present invention.

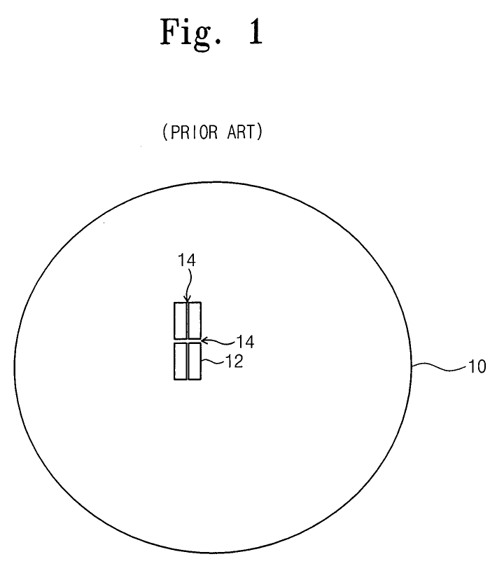

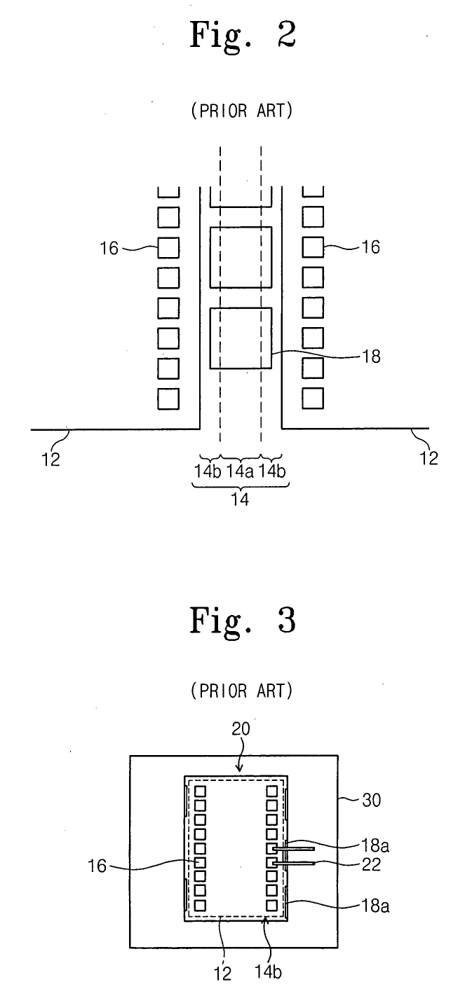

The figures referred to herein are drawn for clarity of illustration and are not necessarily drawn to scale. Elements having the same reference number in FIGS. 1, 2, 3, 4, 5, 6, 7, 8, and 9 refer to elements having similar structure and/or function.

### DETAILED DESCRIPTION OF THE INVENTION

The present invention is now described with reference to the accompanying drawings. This invention, however, may be embodied in many different forms and should not be construed as limited to the embodiments set forth herein. Rather, these embodiments are described so that this disclosure is thorough and complete, and fully conveys the scope of the invention to those skilled in the art. In the drawings, the thicknesses of layers and regions are exaggerated for clarity. It will also be understood that when a layer is referred to as being “on” another layer or substrate, it can be directly on the other layer or substrate, or intervening layers may also be present.

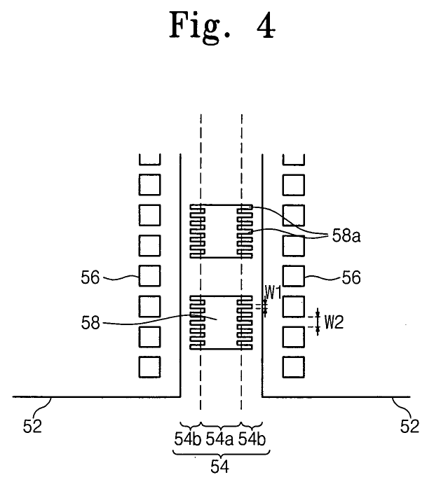

FIG. 4 shows a semiconductor device formed on a semiconductor wafer according to an example embodiment of the present invention. The semiconductor device includes a plurality of chip regions 52 separated by a scribe region 54. Each of the chip regions 52 has a respective set of pads 56 disposed near the scribe region 54.

Further referring to FIG. 4, measurement patterns 58 are formed in the scribe region 54. The measurement patterns 58 may each be a monitoring pattern used for thickness measurement during fabrication of the integrated circuits of the chip regions 52. For example, the measurement patterns 58 may be comprised of a conductive material such as a metal interconnection layer.

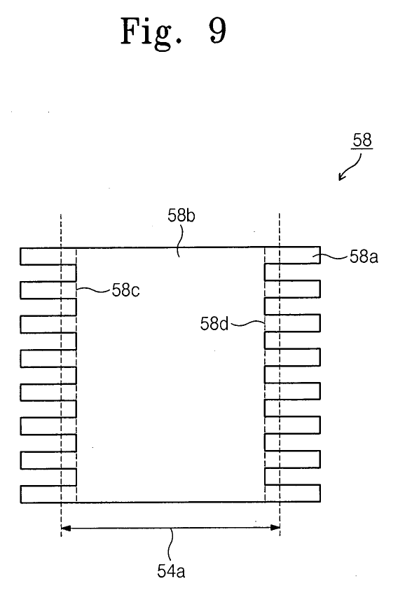

Also referring to FIG. 4, each of the measurement patterns 58 includes line patterns 58a that extend toward the chip regions 52 disposed on both sides of the measurement pattern 58. Referring to FIGS. 4 and 9, each measurement pattern 58 includes a central body 58b that is a continuous rectangular body in an example embodiment of the present invention.

In addition, a first set of line patterns 58a is formed to extend from a left side 58c of the central body 58b toward a first set of pads 56 disposed in the chip region 52 to the left of the scribe line 54. Also, a second set of line patterns 58a is formed to extend from a right side 58d of the central body 58b toward a second set of pads 56 disposed in the chip region 52 to the right of the scribe line 54.

Further referring to FIG. 4, the scribe region 54 includes a removed region 54a to be removed using a saw blade during a sawing operation for forming integrated circuit dies from the chip regions 52. The scribe region 54 also includes a remaining region 54b that remains to surround an integrated circuit die formed after the sawing operation.

In an embodiment of the present invention, the central body 58b of the measurement pattern 58 is completely contained within the removed region 54a. Another words, no portion of the central body 58b of the measurement pattern 58 is disposed in the remaining region 54b. Rather, only the line patterns 58a are formed in the remaining region 54b.

In the example embodiment of FIG. 9, first portions of the line patterns 58a are formed in the remaining region 54b, and second portions of the line patterns 58a are formed in the removed region 54a. Portions of the line patterns 58a are formed in the removed region 54a to account for the positional deviation of the sawing blade. Thus, only the line patterns 58a remain in the remaining region 54b after the chip regions 52 are sawed into integrated circuit dies.

The line patterns 58a are spaced a predetermined distance apart from one another. In addition, each of the line patterns 58a has a respective line-width W1. The pads 56 are arranged in each chip region 52 at regular intervals. The line-width W1 of each of the line patterns 58a is less than a predetermined distance between two adjacent pads 56 in the chip region 52.

For example, the line-width W1 of each of the line patterns 58a is less than a separation interval W2 between the two adjacent pads 56. Alternatively, the line-width W1 of each of the line patterns 58a is less than a pitch between the two adjacent pads 56. The pitch between the two adjacent pads is a distance between a center of one of the adjacent pads to a center of the other of the adjacent pads. In this manner, when interconnection lines 62b are connected to the pads 56 (as illustrated in FIG. 8) with similar pitch as the pads 56 and are disposed over the line patterns 58a remaining in the remaining portion 54b, such interconnection lines 62b are not short-circuited to each-other via the line patterns 58a.

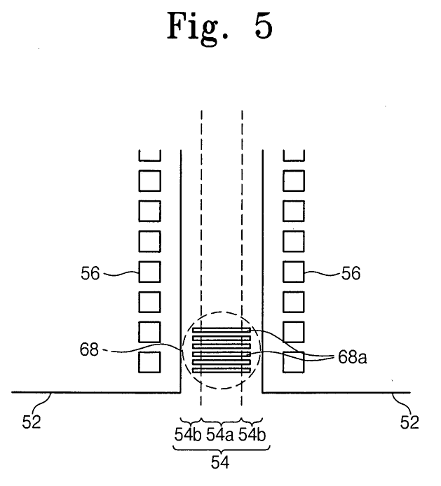

FIG. 5 shows line patterns 68a of a measurement pattern 68 formed in the scribe region 54 between the chip regions 52, according to another example embodiment of the present invention. Such a measurement pattern 68 may be an overlay or alignment key used during fabrication of the integrated circuits of the chip regions 52.

The measurement pattern 68 of FIG. 5 includes line patterns 68a that extend through the removed region 54a and the remaining regions 54b toward the chip regions 52. Thus, the measurement pattern 68 of FIG. 5 does not include any continuous central body. The line patterns 68a are spaced a predetermined distance apart from one another, and each of the line patterns 68a has the line-width W1 that is less than a separation interval W2 between two adjacent pads 56 or less than a pitch between two adjacent pads 56.

When the chip regions 52 are sawed with the saw blade running through the removed region 54a, the portions of the line patterns 68a in the remaining regions 54b remain. Similar to the embodiment of FIG. 4, when interconnection lines 62b are connected to the pads 56 (as illustrated in FIG. 8) with similar pitch as the pads 56 and are disposed over the line patterns 68a remaining in the remaining portion 54b, such interconnection lines 62b are not short-circuited to each-other via the line patterns 68a.

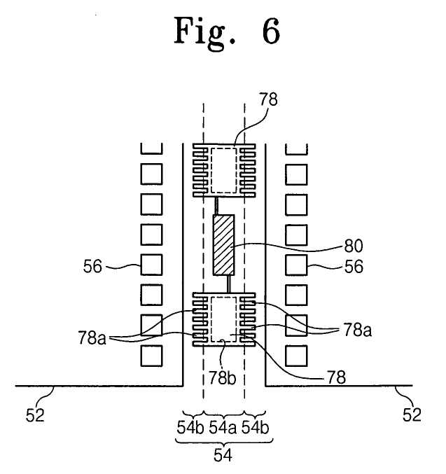

FIG. 6 illustrates a measurement pattern 78 formed in the scribe region 54 between the chip regions 52 according to yet another example embodiment of the present invention. Referring to FIG. 6, each measurement pattern 78 is formed similarly as illustrated in FIG. 4 to include line patterns 78a extending from a central body 78b. Such line patterns 78a and central body 78b are formed similarly to the line patterns 58a and central body 58b, respectively, as described in reference to FIGS. 4 and 9 above. In addition, a test pattern 80 is formed connected to the two measurement patterns 78 through interconnection lines. In that case, the central body 78b of the measurement pattern 78 is used as a probe pad for electrical testing of the test pattern 80.

The line patterns 78a are spaced a predetermined distance apart from one another, and each of the line patterns 78a has the line-width W1 that is less than a separation interval W2 between two adjacent pads 56 or less than a pitch between two adjacent pads 56. When the chip regions 52 are sawed with the saw blade running through the removed region 54a, the portions of the line patterns 78a in the remaining regions 54b remain. Similar to the embodiment of FIG. 4, when interconnection lines 62b are connected to the pads 56 (as illustrated in FIG. 8) with similar pitch as the pads 56 and are disposed over the line patterns 78a remaining in the remaining portion 54b, such interconnection lines 62b are not short-circuited to each-other via the line patterns 78a.

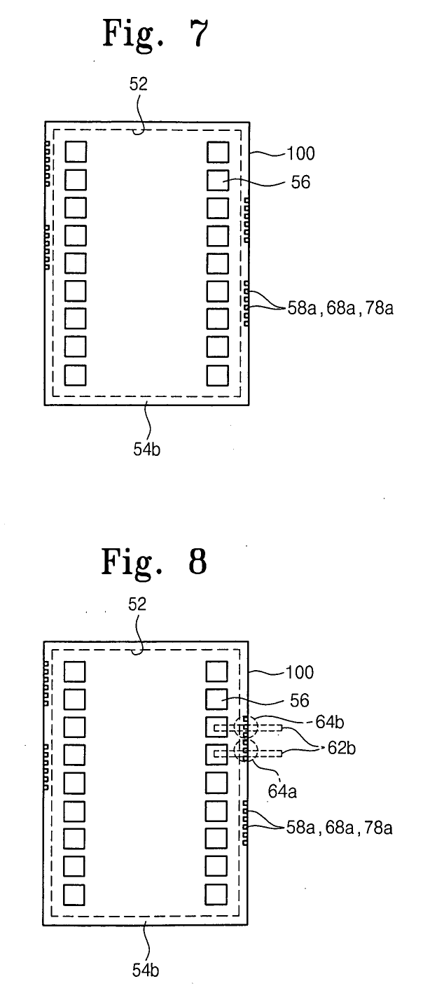

FIGS. 7 and 8 illustrate a semiconductor chip 100 of the semiconductor device of FIG. 4, 5, or 6 after having been sawed to form an integrated circuit die according to an example embodiment of the present invention. Referring to FIG. 7, the semiconductor chip 100 includes the chip region 52 and the remaining scribe region 54b disposed around the chip region 52.

The pads 56 are arranged at regular intervals in the chip region 52. In addition, portions of the line patterns 58a, 68a, or 78a of FIG. 4, 5, or 6 remain in the remaining scribe region 54b. The remaining conductive line patterns 58a, 68a, or 78a may have the shape of dots or lines, which are spaced a predetermined distance apart from one another, depending on the position of a blade used for the separation of semiconductor chips.

Referring to FIG. 8, when packaging the semiconductor chip 100, interconnection lines 62b are connected to the pads 56 and may contact the remaining conductive patterns 58a, 68a, or 78a. In the prior art, the remaining conductive patterns extend along the boundary of the semiconductor chip and cause short-circuiting between the interconnection lines. In contrast in the present invention, since the remaining conductive patterns 58a, 68a, or 78a are arranged at predetermined intervals with short line-width, a portion 64a of the remaining conductive patterns 58a, 68a, or 78a contacting one interconnection line 62b is not electrically connected to another portion 64b of the remaining conductive patterns 58a, 68a, or 78a contacting another interconnection line 62b. Thus, the interconnection lines 62b are not short-circuited to each-other via the remaining conductive patterns 58a, 68a, or 78a.

While the present invention has been particularly shown and described with reference to an exemplary embodiment thereof, it will be understood by those of ordinary skill in the art that various changes in form and details may be made therein without departing from the spirit and scope of the present invention as defined by the following claims.

The present invention is limited only as defined in the following claims and equivalents thereof.

What is claimed is:

1. A semiconductor device comprising:
pads disposed in a chip region of a semiconductor substrate; and
line patterns disposed in a scribe region of the semiconductor substrate and extending toward the pads, wherein the line patterns each are spaced apart.

2. The semiconductor device of claim 1, wherein the line-width of each line pattern is less than an interval between adjacent pads.

3. The semiconductor device of claim 1, wherein the line-width of each line pattern is less than a pitch between adjacent pads.

4. The semiconductor device of claim 1, further including:
a measurement pattern including a central body and the line patterns extending from the central body toward the pads.

5. The semiconductor device of claim 4, further including:
a first set of pads disposed in a first chip region of the semiconductor substrate that is a semiconductor wafer;
a second set of pads disposed in a second chip region of the semiconductor substrate;
a first set of line patterns extending from a first side of the central body toward the first set of pads; and
a second set of line patterns extending from a second side of the central body toward the second set of pads.

6. The semiconductor device of claim 4, wherein the central body is a continuous rectangular body.

7. The semiconductor device of claim 4, wherein the measurement pattern is used for monitoring a thickness of the measurement pattern.

8. The semiconductor device of claim 4, wherein the measurement pattern is used as an overlay or alignment key.

9. The semiconductor device of claim 4, wherein the central body is completely contained within a removed region of the scribe region.

10. The semiconductor device of claim 4, further comprising:
a test pattern formed in the removed region of the scribe region, wherein the test pattern is connected to the measurement pattern.

11. The semiconductor device of claim 10, wherein the measurement pattern is used as a probe pad for the test pattern.

12. The semiconductor device of claim 4, wherein the central body is not disposed in a remaining region of the scribe region.

13. The semiconductor device of claim 12, wherein first portions of the line patterns are disposed in a removed region of the scribe region, and wherein second portions of the line patterns are disposed in a remaining region of the scribe region.

14. The semiconductor device of claim 4, wherein the measurement pattern is comprised of a conductive material.

15. The semiconductor device of claim 1, wherein the line patterns extend through a removed region and a remaining region of the scribe region.

16. The semiconductor device of claim 15, wherein the line patterns are comprised of a conductive material.

17. The semiconductor device of claim 1, wherein the line patterns are disposed in a remaining region of the scribe region after the chip region has been sawed to form an integrated circuit die.

18. The semiconductor device of claim 17, further comprising:
a respective interconnection line connected to each of the pads and being disposed over a respective portion of the line patterns.

19. The semiconductor device of claim 18, wherein the respective interconnection lines and the line patterns are each comprised of a conductive material.

20. The semiconductor device of claim 19, wherein the respective interconnection lines connected to the pads are not short-circuited to each-other through the line patterns.
